(19) United States
(12) Patent Application Publication
(10) Pub. No.: US 2010/0148294 A1
(43) Pub. Date: Jun. 17, 2010

(54) OPTICAL DEVICE AND ELECTRONIC DEVICES USING THE SAME

(75) Inventors: Kyoko FUJII, Osaka (JP); Takahiro Nakano, Kyoto (JP); Hikari Sano, Hyogo (JP)

Correspondence Address: MCDERMOTT WILL & EMERY LLP, 600 13TH STREET, NW, WASHINGTON, DC, 20005-3096, US

(73) Assignee: Panasonic Corporation, Osaka (JP)

(21) Appl. No.: 12/712,420

(22) Filed: Feb. 25, 2010

Related U.S. Application Data
(63) Continuation of application No. PCT/JP2009/000961, filed on Mar. 3, 2009.

(30) Foreign Application Priority Data
Apr. 25, 2008 (JP) 2008-116018
Apr. 25, 2008 (JP) 2008-116022
Feb. 17, 2009 (JP) 2009-034233

(51) Int. Cl. H01L 31/0216

(52) U.S. Cl. 257/435; 257/E31.122

(57) ABSTRACT

An optical device such as an image sensor alleviates reduction in image quality caused by light reaching a peripheral circuit section other than a light receiving section. A semiconductor substrate includes an interconnect layer, a light receiving section provided with a plurality of light receiving elements on the interconnect layer, and a peripheral circuit section provided in a same layer as the light receiving section, and surrounding the light receiving section. Light entry elements are provided on a surface of the semiconductor substrate. A light shielding film is formed of a metal layer, and covers at least one part of a region corresponding to the peripheral circuit section. A first electrode is formed in the region corresponding to the peripheral circuit section, and in an opening of the light shielding film to be electrically isolated from the light shielding film.

### CROSS-REFERENCE TO RELATED APPLICATION

This is a continuation of PCT International Application PCT/JP2009/000961 filed on Mar. 3, 2009, which claims priority to Japanese Patent Application Nos. 2008-116018, 2008-116022, and 2009-034233 filed on Apr. 25, 2008, Apr. 25, 2008, and Feb. 17, 2009, respectively. The disclosures of these applications including the specifications, the drawings, and the claims are hereby incorporated by reference in their entirety.

### BACKGROUND

The present disclosure relates to optical devices such as image sensors, and electronic devices such as cameras using the optical devices.

An image sensor, which represents optical devices suggested in recent years, has the following structure. The sensor includes a semiconductor substrate having an imaging section provided with a plurality of light receiving elements, and a peripheral circuit section surrounding the imaging section. A plurality of micro-lenses are provided in a part corresponding to the imaging section on a surface of the semiconductor substrate.

Japanese Patent Publication No. 2006-32561 describes, as a similar structure, a semiconductor image sensor module with a reduced size and weight. The structure shown in the publication is of a so-called “back surface projection type.” To be specific, micro-lenses are provided on a back surface of a substrate (i.e., on the opposite side to the surface, on which an interconnect layer is formed). Light is incident from the back surface. When viewed from the direction of the light incidence, the elements are arranged in the following order: the micro-lenses, the light receiving elements, and the interconnect layer. On the other hand, in a conventional so-called “front surface projection type” structure, light is incident from a surface provided with an interconnect layer. When viewed from the direction of light incidence, the elements are arranged in the following order: the micro-lenses, the interconnect layer, and the light receiving elements.

### SUMMARY

In the image sensor having the above-described structure, image information is, as optical signals, input to the light receiving elements in an imaging section via the micro-lenses, and converted to electrical signals by the light receiving elements. However, the incident light also reaches a peripheral circuit section surrounding the imaging section other than the imaging section. As a result, quality of the image converted to the electrical signals is degraded.

To be specific, the peripheral circuit section includes semiconductor elements. When light reaches the semiconductor elements, electrical properties of the semiconductor elements are changed. This results in degradation in the quality of the image converted to the electrical signals. This problem is not limited to image sensors but is commonly seen in all types of optical devices.

In particular, in a back surface projection type structure, incident light reaches the light receiving elements without passing through the interconnect layer. This type is thus, preferable in terms of light sensitivity. However, since the light does not pass through the interconnect layer, this structure allows a larger amount of light to enter the peripheral circuit section than a front surface projection type structure. This leads to significant degradation in the image quality cased by a change in properties of the peripheral circuit section.

It is thus an objective of the present disclosure to alleviate degradation in quality of image caused by light, which reaches a peripheral circuit section other than a light receiving section of an imaging section in an optical device such as an image sensor.

An optical device according to the present disclosure includes a semiconductor substrate including an interconnect layer, a light receiving section provided with a plurality of light receiving elements on the interconnect layer, and a peripheral circuit section provided in a same layer as the light receiving section, and surrounding the light receiving section; light entry elements provided in a region corresponding to the light receiving section on an outer surface of one surface of the semiconductor substrate located above the light receiving section and the peripheral circuit section; a light shielding film formed of a metal layer, and covering at least one part of a region corresponding to the peripheral circuit section; and a first electrode formed in the region corresponding to the peripheral circuit section, and in an opening of the light shielding film to be electrically isolated from the light shielding film.

According to the present disclosure, the light entry elements are provided in the region corresponding to the light receiving section on the one surface of the semiconductor substrate, which is on the opposite side to the interconnect layer. That is, the device in the present disclosure is of the so-called “back surface projection type.” On the one surface, the light shielding film is provided on the region corresponding to the peripheral circuit section. This structure decreases the amount of light entering the peripheral circuit section to reduce a change in electrical properties of the peripheral circuit section. As a result, degradation in image quality can be alleviated.

According to the present disclosure, degradation in image quality caused by a change in electrical properties of the peripheral circuit section can be alleviated in an optical device.

### BRIEF DESCRIPTION OF THE DRAWINGS

FIG. 1 is a perspective view of an optical device according to a first embodiment.

FIG. 2 is an enlarged sectional view of the optical device shown in FIG. 1.

FIG. 3 is a partial enlarged sectional view illustrating the structure shown in FIG. 2.

FIG. 4 is a partial enlarged sectional view illustrating another structure.

FIG. 5 is a partial enlarged sectional view illustrating another structure.

FIG. 6 is a partial enlarged sectional view illustrating another structure.

FIG. 7 is a perspective view illustrating another structure of the optical device according to the first embodiment.

FIG. 8 is a perspective view of an optical device according to a second embodiment.

FIG. 9 is a cross-sectional view of the optical device shown in FIG. 8.

FIGS. 10A-10E are cross-sectional views illustrating an example method of manufacturing the optical device shown in FIG. 8.

FIGS. 11A-11D are cross-sectional views illustrating the example method of manufacturing the optical device shown in FIG. 8.

FIGS. 12A and 12B are cross-sectional views illustrating the example method of manufacturing the optical device shown in FIG. 8.

FIG. 13 is a perspective view illustrating a state where the optical device of FIG. 8 is mounted in an electronic device.

FIG. 14 is a cross-sectional view of the structure shown in FIG. 13.

### DETAILED DESCRIPTION

Embodiments of the present disclosure will be described hereinafter with reference to the drawings. An image sensor is used for explanation as an example of an optical device. However, the optical device of the present disclosure is not limited to an image sensor, but may include a light receiving section such as a photo IC or a laser diode.

### Embodiment 1

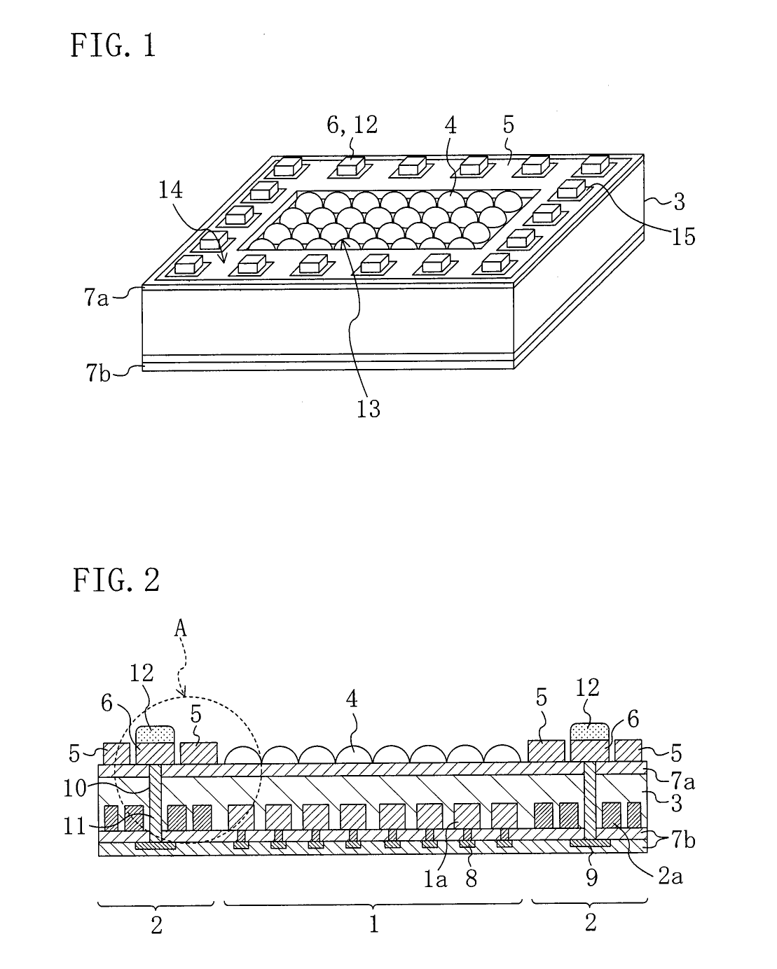

FIG. 1 is a perspective view of an image sensor as an optical device according to a first embodiment. FIG. 2 is a vertical sectional view of the image sensor shown in FIG. 1. The image sensor according to this embodiment is of the so-called “back surface projection type.”

In FIGS. 1 and 2, a semiconductor substrate 3 includes in a layer, a light receiving section 1 provided with a plurality of light receiving elements 1a, and a peripheral circuit section 2 surrounding the light receiving section 1 and provided with a plurality of circuit elements 2a. When the device is an image sensor, the light receiving section 1 serves as an imaging section. The circuit elements 2a of the peripheral circuit section 2 are arranged in a substantially square frame at the outer edge of the semiconductor substrate 3. The light receiving elements 1a of the light receiving section 1 are arranged in a space having a substantially square shape inside the peripheral circuit section 2.

Furthermore, the semiconductor substrate 3 has a multilayer structure, and both surfaces of the semiconductor substrate are covered with insulating films 7a and 7b. In a lower surface (corresponding to the “other surface”), interconnections 8, which are electrically connected to the respective light receiving elements 1a, are buried in the insulating film 7b to form an interconnect layer of the semiconductor substrate 3.

On an outer surface of an upper surface (referred to as “one surface”) of the semiconductor substrate 3, a plurality of micro-lenses 4 are provided as light entry elements in a region 13 corresponding to the light receiving section 1. On the same outer surface, first electrodes 6 are provided in a region 14 corresponding to the peripheral circuit section 2 and surrounding the micro-lenses 4. In the region 14, the part other than the first electrodes 6 is covered with a light shielding film 5. That is, the light shielding film is formed on the surface of the semiconductor substrate 3, which is on the opposite side to the interconnect layer (on the surface provided with the micro-lenses 4), to cover the peripheral circuit section 2.

Furthermore, second electrodes 9 are provided on an outer surface of a lower surface of the semiconductor substrate 3. The first electrodes 6 on the upper surface and the second electrodes 9 on the lower surface are electrically connected together by pillar-shaped conductive bodies 11, which are provided to penetrate the semiconductor substrate 3. In order to form the conductive bodies 11, the semiconductor substrate 3 is provided with a plurality of through holes 10. Moreover, bumps 12 made of solder, gold, or the like are formed on surfaces of the first electrodes 6.

When the image sensor of FIGS. 1 and 2 is viewed from above, there are a region exposing the micro-lenses 4, and a region surrounding the exposing region and covered with the light shielding film 5. The light shielding film 5 includes square openings 15. The first electrodes 6 are formed in the openings 15. The light shielding film 5 is formed of a metal layer. The first electrodes 6 are electrically isolated from the light shielding film 5 by the openings 15. The first electrodes 6 can be formed by isolating parts of the light shielding film 5 like islands.

In the structure shown in FIGS. 1 and 2, when light is irradiated from above, the light illuminates not only the region 13 but also the region 14. However, since the region 14 is covered with the light shielding film 5 and the first electrodes 6, much less light than in a conventional technique reaches the peripheral circuit section 2. The amount is extremely small. Thus, electrical properties are not changed in the peripheral circuit section 2. This alleviates degradation in image quality. FIG. 1 shows that the part of the region 14 other than the first electrodes 6 is almost entirely covered with the light shielding film 5. However, it may be partially covered with the light shielding film 5.

Furthermore, since the first electrodes 6 are provided on the same surface as the micro-lenses 4, from which light enters; the image sensor can be connected to subsequent circuits such as a test circuit of the image sensor, and a processing circuit of the electronic device on the light incidence plane. For example, in testing, an electrode for testing can be in contact with the bump 12 on the surface of one of the first electrodes 6 so that light can be irradiated from above toward the micro-lenses 4. That is, this greatly improves testing efficiency. Also, minimization of the electronic device mounting the image sensor can be facilitated. Note that the first electrodes 6 may not be formed on the same surface as the micro-lenses 4.

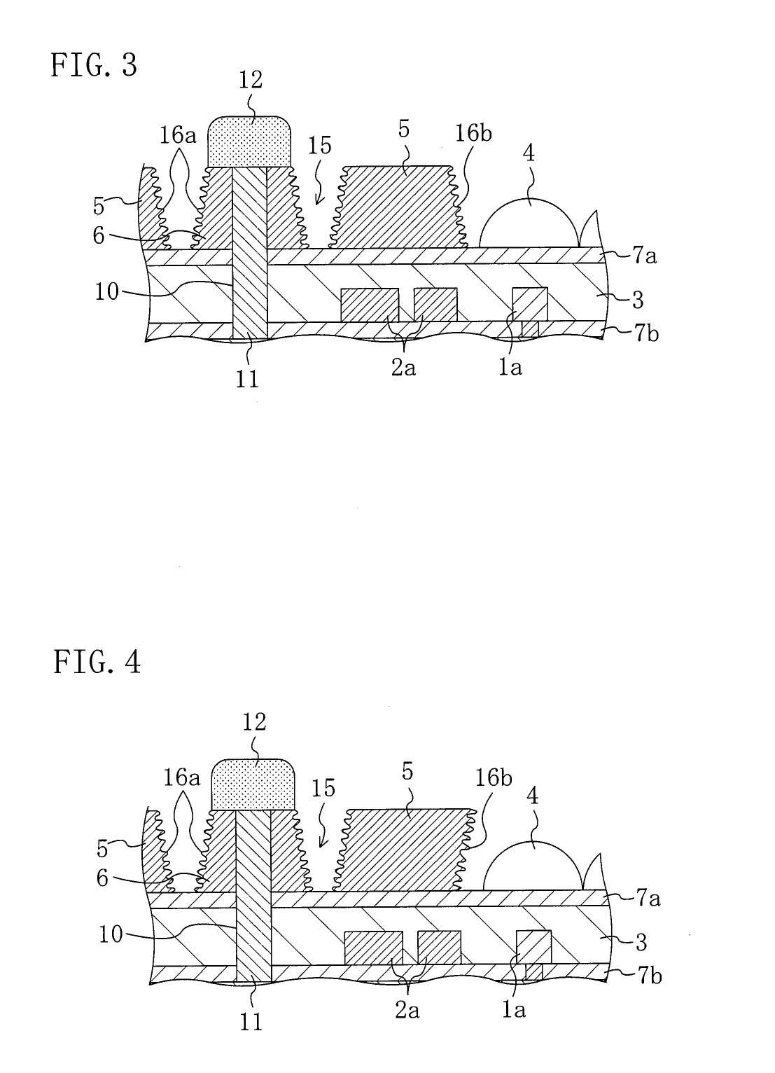

FIG. 3 is an enlarged view of a part A in FIG. 2; in which the light shielding film 5, the first electrodes 6, and the micro-lenses 4 are arranged. As shown in FIG. 3, in this embodiment, the light shielding film 5 and the first electrodes 6 are formed to have thicknesses larger than the micro-lenses 4. In this structure, light hardly enters the inside of the openings 15, for example, to further reduce the amount of light reaching the peripheral circuit section 2.

Inner walls of the openings 15, i.e., end surfaces 16a of the light shielding film 5 and the first electrodes 6 in a wall thickness direction have rough surfaces. This reduces light reflection within the openings 15 to further reduce the amount of light reaching peripheral circuit section 2.

Furthermore, an end surface 16b of the light shielding film 5, which faces the micro-lenses 4, i.e., the end surface at the side of the micro-lenses in the thickness direction, preferably has a rough surface, as well. This greatly reduces light reflection from the end surface 16b toward the micro-lenses 4 to decrease undesired reflected light from the light shielding film 5.

An example method of manufacturing the image sensor according to this embodiment, particularly the light shielding film 5 and the first electrodes 6, will be described hereinafter with reference to FIG. 3.

First, the micro-lenses 4 are formed on the insulating film 7a on the upper surface of the semiconductor substrate 3 by spin coat processing. At this time, the light shielding film 5 and the first electrodes 6 are not formed yet.

Then, a copper thin film is formed on the insulating film 7a and the micro-lenses 4 on the upper surface of the semiconductor substrate 3 by, for example, deposition. Thereafter, the micro-lenses 4 and the outer periphery of the micro-lenses 4 are covered with a resist film, which has a thickness sufficient to cover the micro-lenses 4 (a thickness larger than the micro-lenses 4 in FIG. 3).

Next, the resist film is covered with a mask having an open part to be provided with the light shielding film 5 and the first electrodes 6 later. In this state, blast processing, dry etching, and the like are performed from a top of the mask. This removes the resist film in the part to be provided with the light shielding film 5 and the first electrodes 6. The copper thin film is left unremoved.

When electrolytic plating is performed in this state using the copper thin film, the light shielding film 5 and the first electrodes 6 are formed, which have thicknesses larger than the micro-lenses 4 as shown in FIG. 3. Then, the entire resist film is removed by etching, the openings 15 are formed between the light shielding film 5 and the first electrodes 6, as shown in FIG. 3. Also, the micro-lenses 4 are exposed. However, the copper thin film is left on an insulating film 7a under the formed openings 15 and on the exposed micro-lenses 4. Thus, the copper thin film in these parts is removed by etching.

Furthermore, the through holes 10 and the conductive bodies 11 are formed. The bumps 12 are provided on the surfaces of the first electrodes 6 at the end. As a result, the structure shown in FIG. 3 is completed.

The following procedure is used to roughen the surfaces of the inter walls 16a of the openings 15, and the end surface 16b of the light shielding film 5. When removing the resist film by, for example, blast processing and dry etching, asperities may be formed on a surface of the resist film. As such, the surfaces of the inter walls 16a of the openings 15, and the end surface 16b of the light shielding film 5 can be easily roughen by electroplating at later time.

Since the light shielding film 5 and the first electrodes 6 are formed by the above-described procedure, the structure in FIG. 3 can be easily modified to the structures shown in, e.g., FIGS. 4-6.

To be specific, in the structure shown in FIG. 3, each of the openings 15 has a width which gradually decreases toward the semiconductor substrate 3. The end surface 16b of the light shielding film 5 near the micro-lenses 4 is inclined to be closer to the micro-lenses 4 at the side of the semiconductor substrate 3. That is, the light shielding film 5 and the first electrodes 6 gradually expand toward the semiconductor substrate 3 in the cross section.

On the other hand, in the structure shown in FIG. 4, the end surface 16b of the light shielding film 5 near the micro-lenses 4 is inclined to be farther from the micro-lenses 4 at the side of the semiconductor substrate 3.

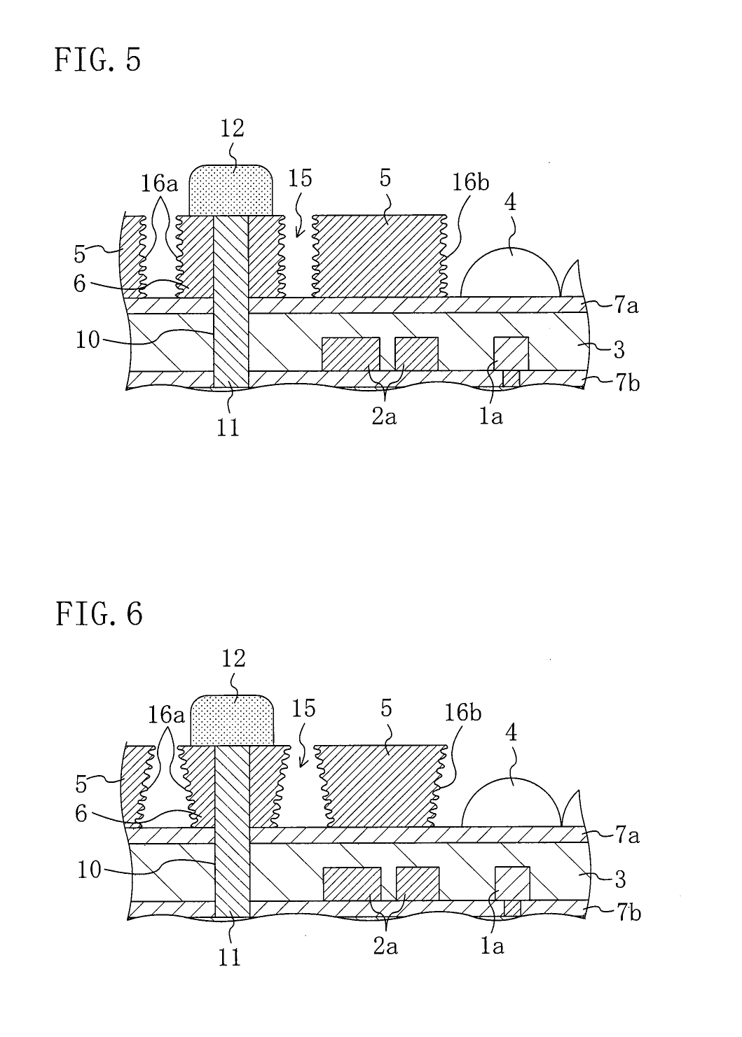

In the structure shown in FIG. 5, the inter walls 16a of the openings 15 and the end surface 16b of the light shielding film 5 near the micro-lenses 4 are almost perpendicular to the surface of the semiconductor substrate 3.

In the structure shown in FIG. 6, each of the openings 15 gradually expands toward the semiconductor substrate 3. The end surface 16b of the light shielding film 5 near the micro-lenses 4 is inclined to be farther from the micro-lenses 4 at the side of the semiconductor substrate 3. That is, the light shielding film 5 and the first electrodes 6 gradually narrow toward the semiconductor substrate 3 in the cross section.

While in the above-described embodiment, the light shielding film 5 is formed of a metal layer; the light shielding film 5 may be made of, for example, a colored (e.g., black) synthetic resin.

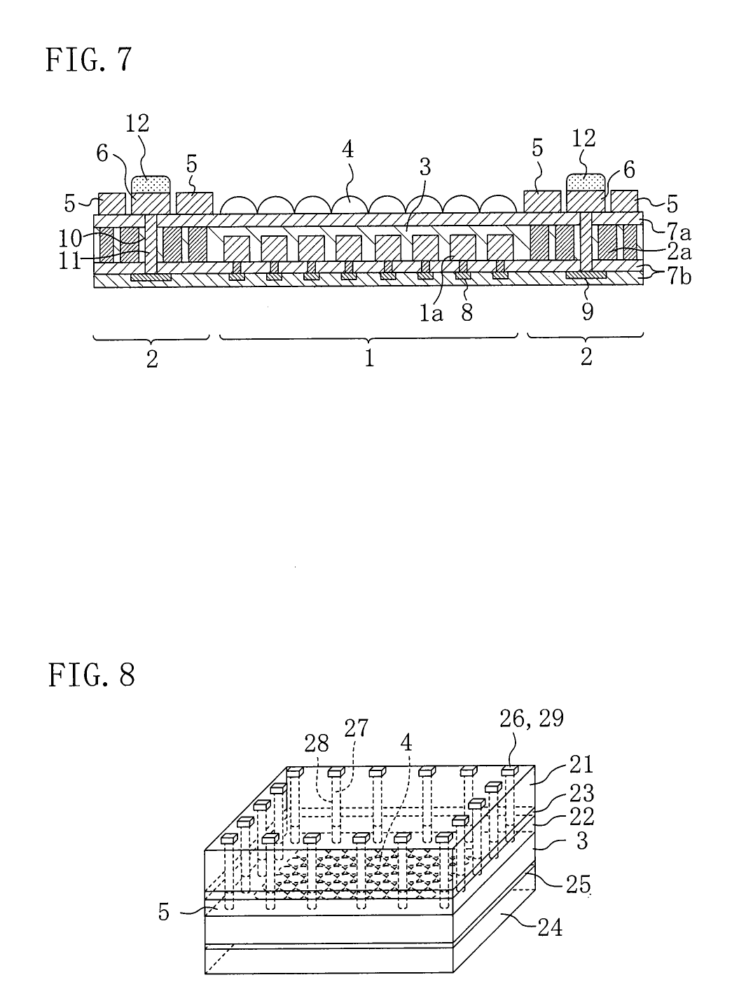

FIG. 7 is a vertical sectional view illustrating another structure of the image sensor according to this embodiment. In FIG. 7, the same reference characters are assigned to the same elements as those shown in FIG. 2, and detailed description thereof is omitted. In the structure shown in FIG. 7, a lower surface of the insulating film 7a, which is formed in a surface portion of the one surface, is flush with upper surfaces of the circuit elements 2a in the peripheral circuit section 2, on the side of the semiconductor substrate 3 with the micro-lenses 4 and the light shielding film 5.

When incident light from an oblique angle is taken into consideration, the distance between the peripheral circuit section 2 and the light shielding film 5 is preferably small. Ideally, the light shielding film 5 is arranged directly above the circuit elements 2a. In a back surface projection type, since the interconnect layer is on the opposite side to the light shielding film 5, such arrangement is possible. Thus, as shown in FIG. 7, since the lower surface of the insulating film 7a under the light shielding film 5 is flush with the upper surfaces of the circuit elements 2a of the peripheral circuit section 2, the distance between the peripheral circuit section 2 and the light shielding film 5 can be extremely small. This minimizes effects of incident light from an oblique angle.

In the structure of FIG. 7, the upper surfaces of the circuit elements 2a are flush with the lower surface of the insulating film 7a. However, when the light receiving elements 1a are taller than the circuit elements 2a, an upper surface of the light receiving section 1 may be flush with the lower surface of the insulating film 7a. In this structure, similar advantages to those in FIG. 7 can be obtained.

### Embodiment 2

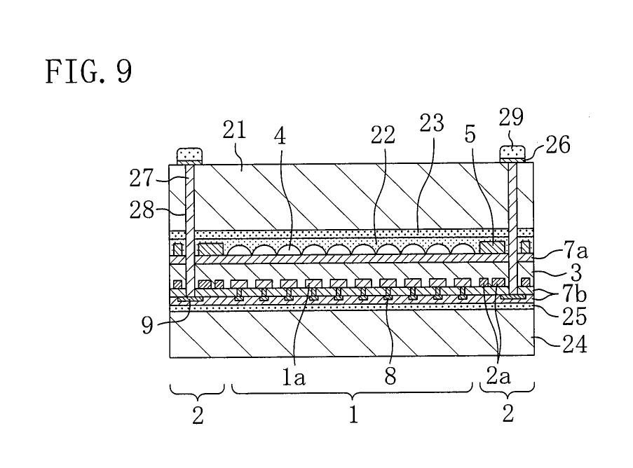

FIG. 8 is a perspective view of an image sensor as an optical device according to a second embodiment. FIG. 9 is a vertical sectional view of the image sensor shown in FIG. 8. In FIGS. 8 and 9, the same reference characters are assigned to the same elements as those shown in FIGS. 1 and 2. The image sensor according to this embodiment is also of the so-called “back surface projection type.”

In FIGS. 8 and 9, a semiconductor substrate 3 includes a light receiving section 1 provided with a plurality of light receiving elements 1a, and a peripheral circuit section 2 surrounding the light receiving section 1 and provided with a plurality of circuit elements 2a. When the device is an image sensor, the light receiving section 1 servers as an imaging section. The circuit elements 2a of the peripheral circuit section 2 are arranged in a substantially square frame at the outer edge of the semiconductor substrate 3. The light receiving elements 1a of the light receiving section 1 are arranged in a space having a substantially square shape inside the peripheral circuit section 2.

Furthermore, the semiconductor substrate 3 has a multilayer structure, and both surfaces of the semiconductor substrate are covered with insulating films 7a and 7b. In a lower surface (referred to as the “other surface”), interconnections 8, which are electrically connected to the respective light receiving elements 1a, are buried in the insulating film 7b to form an interconnect layer of the semiconductor substrate 3.

On an outer surface of an upper surface (referred to as “one surface” being a light receiving surface) of the semiconductor substrate 3, a plurality of micro-lenses 4 are provided in a region corresponding to the light receiving section 1. On the same outer surface, a region corresponding to the peripheral circuit section 2 surrounding the micro-lenses 4 are covered with the light shielding film 5. A transparent cover 21 made of, e.g., glass is provided over the upper surface of the semiconductor substrate 3. The transparent cover 21 is bonded to a low refractive index layer 22 formed on the semiconductor substrate 3 with a transparent adhesive 23.

A reinforcement board 24 made of, e.g., glass is provided on the lower surface of the semiconductor substrate 3. The reinforcement board 24 is bonded to the insulating film 7b of the semiconductor substrate 3 with transparent adhesive 25.

First electrodes 26 are provided on a surface of the transparent cover 21, which is on the opposite side to the semiconductor substrate 3. Second electrodes 9 are provided on an outer surface of a lower surface of the semiconductor substrate 3. The first electrodes 26 and the second electrodes 9 are electrically connected together by pillar-shaped conductive bodies 27, which are provided to penetrate the semiconductor substrate 3, the light shielding film 5, and the transparent cover 21. In order to form the conductive bodies 27, the semiconductor substrate 3 and the transparent cover 21 are provided with a plurality of through holes 28. The conductive bodies 27 are electrically isolated from the light shielding film 5. Moreover, bumps 29 made of solder, gold, or the like are formed on surfaces of the first electrodes 26.

In the structures of FIGS. 8 and 9, on the light receiving surface of the semiconductor substrate 3, the region corresponding to the peripheral circuit section 2 and surrounding the micro-lenses 4 is covered with the light shielding film 5. Thus, when light is irradiated, much less light than in a conventional technique reaches the peripheral circuit section 2. The amount is extremely small. Thus, electrical properties are not changed in the peripheral circuit section 2. This alleviates degradation in image quality. The region corresponding to the peripheral circuit section 2 is not necessarily entirely covered with the light shielding film 5, and may be partially covered with the light shielding film 5.

Since the transparent cover 21 is provided on the light receiving surface of the semiconductor substrate 3, disadvantages can be reduced, such as attachment of dust to the micro-lenses 4 causing degradation of optical information entering the light receiving section 1. Also in this respect, degradation in the image quality can be alleviated.

Furthermore, the transparent cover 21 is integrated with the semiconductor substrate 3 by the conductive bodies 27 provided within the through holes 28 to function as a reinforcement body for reducing curving of the semiconductor substrate 3. This prevents disorder of a planar arrangement of the light receiving elements 1a on the semiconductor substrate 3. Also, in this respect, degradation in the image quality can be alleviated. In view of the reinforcement, the transparent cover 21 preferably has a thickness larger than the reinforcement board 24.

The first electrodes 26 are provided on the surface of the transparent cover 21. The first electrodes 26 are connected to the second electrodes 9 on the semiconductor substrate 3 via the conductive bodies 27. Thus, at the side of the transparent cover 21, from which light enters; image sensor can be connected to subsequent circuits such as a test circuit of the image sensor and a processing circuit provided on a mounting substrate of the electronic device. For example, in testing, an electrode for testing can be in contact with the bumps 29 on the surfaces of the first electrodes 26 so that light can be irradiated from above the transparent cover 21. That is, testing efficiency is greatly improved.

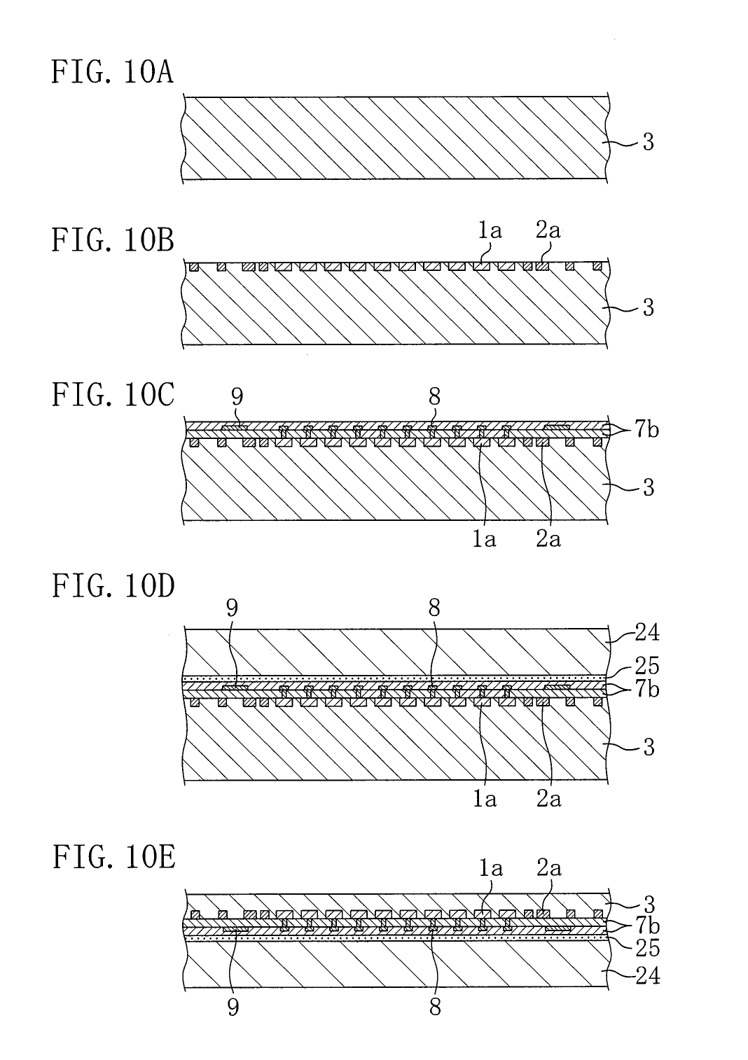

An example method of manufacturing the image sensor having a structure shown in FIGS. 8 and 9 will be described hereinafter with reference to FIGS. 10A-12B.

First, as shown in FIGS. 10A and 10B, the plurality of light receiving elements 1a constituting the light receiving section 1, and the plurality of circuit elements 2a constituting the peripheral circuit section 2 are formed separately on the semiconductor substrate 3, which is a large plate, by a semiconductor process. Then, as shown in FIG. 10C, the insulating film 7b is formed, which is a multilayer film, while forming the second electrodes 9 and the interconnections 8. Thereafter, as shown in FIG. 3D, the reinforcement board 24 is bonded to the semiconductor substrate 3 with the transparent adhesive 25.

Next, as shown in FIG. 10E, with the use of the reinforcement board 24 as a base, the surface of the semiconductor substrate 3 on the opposite side to the light receiving elements 1a is grinded. The grinding makes the semiconductor substrate 3 thinner than in FIG. 10D, as shown in FIG. 10E. This reduction in the thickness allows optical information to pass through the semiconductor substrate 3.

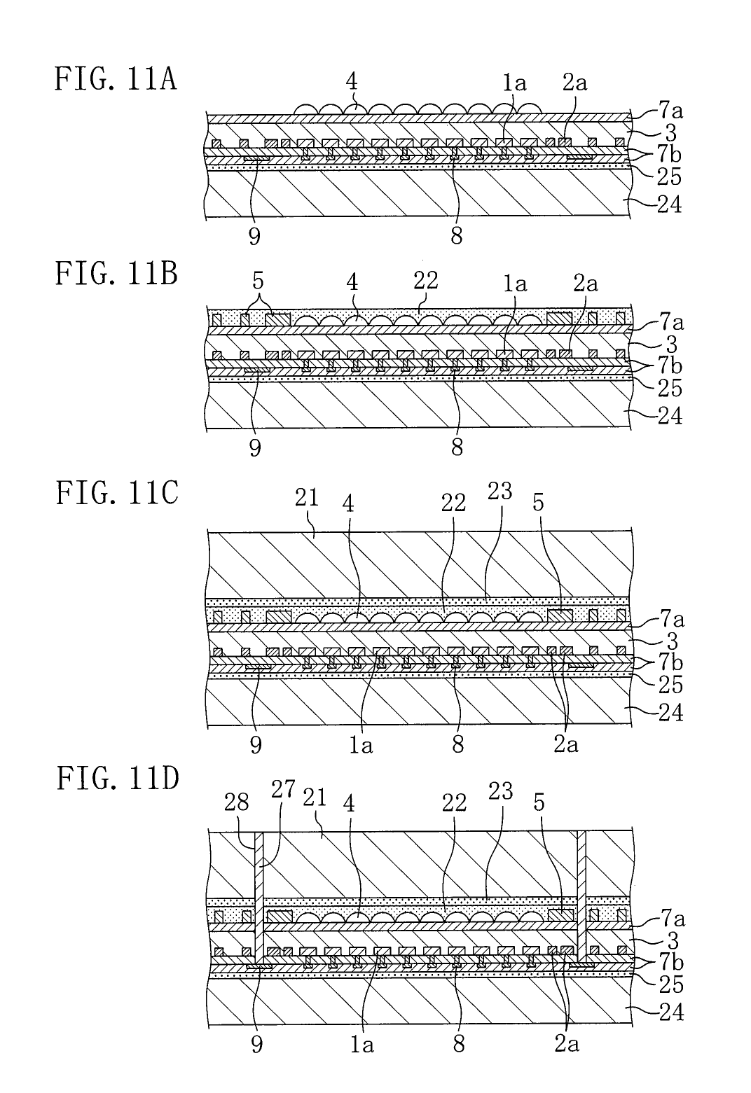

Then, as shown in FIG. 11A, the insulating film 7a is provided on the thinned semiconductor substrate 3. The plurality of micro-lenses 4 are formed on the insulating film 7a through the process of conventional spin coat processing, exposure using a mask, and development. Thereafter, as shown in FIG. 11B, the light shielding film 5 is formed in the region corresponding to the peripheral circuit section 2 and located outside the plurality of micro-lenses 4 on the insulating film 7a using, for example, a metal layer or a colored synthetic resin. Then, the micro-lenses 4 and the light shielding film 5 are covered with the low refractive index layer 22. As shown in FIG. 11C, the transparent cover 21 is bonded to a top of the low refractive index layer 22 with the transparent adhesive 23.

Thereafter, as shown in FIG. 11D, the through holes 28 are formed; which penetrate the transparent cover 21, the transparent adhesive 23, the low refractive index layer 22, the light shielding film 5, the insulating film 7a, and the semiconductor substrate 3; and reach the upper surface of the second electrodes 9. Then, the conductive bodies 27 are formed within the through holes 28. When the light shielding film 5 is formed of a metal layer, an insulating space is provided between the light shielding film 5 and the conductive bodies 27 to include the low refractive index layer 22 within the insulating space. This enables the electrical insulation between the light shielding film 5 and the conductive bodies 27. It is apparent that the conductive bodies 27 are also electrically isolated from the circuit elements 2a in the peripheral circuit section 2.

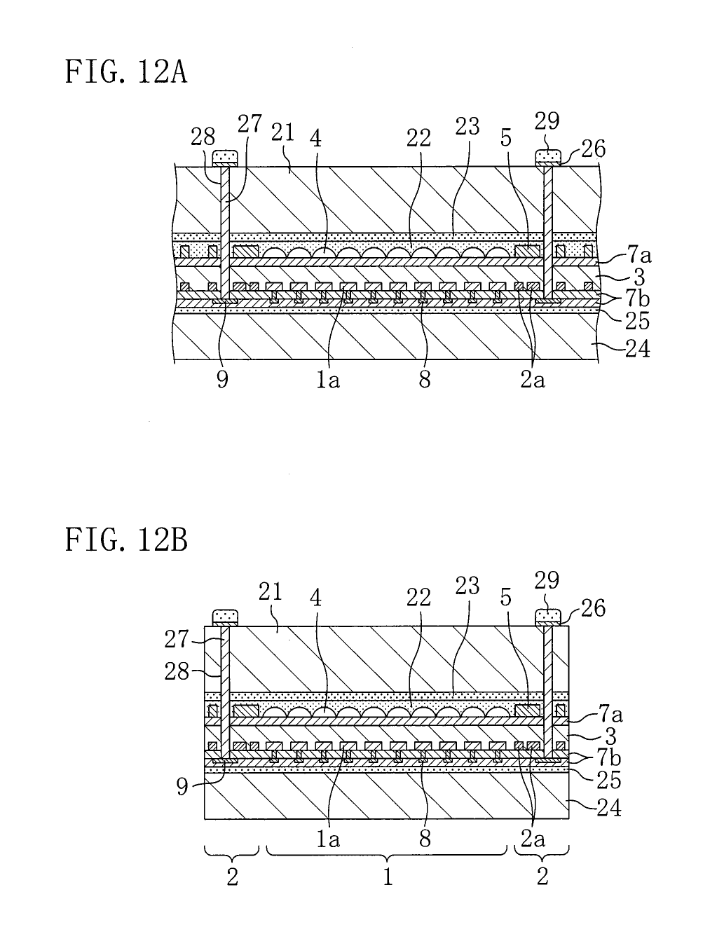

After that, as shown in FIG. 12A, the first electrodes 26 are provided, which are connected to the conductive bodies 27 on the transparent cover 21. Then, the bumps 29 are formed on the surfaces of the first electrodes 26. At the end, optical devices, which are individual pieces separated from the big plate are cut as shown in FIG. 12B.

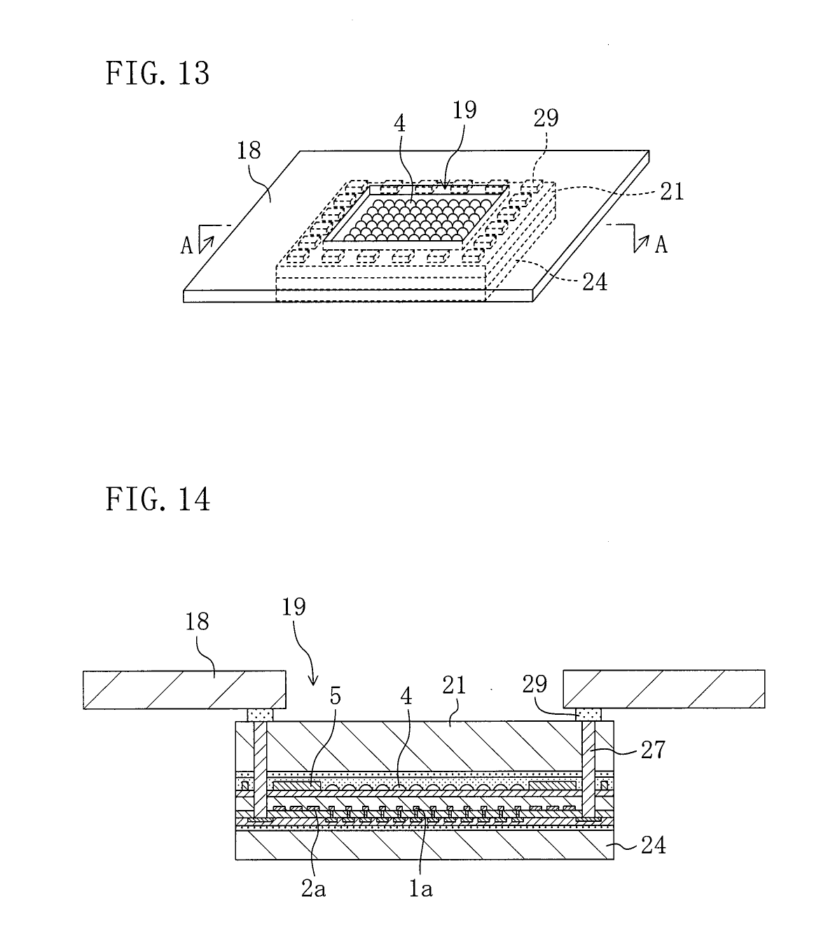

FIG. 13 is a perspective view of the image sensor according to this embodiment mounted on a mounting substrate of an electronic device. FIG. 14 is a cross-sectional view taken along the line A-A in FIG. 13. In FIGS. 13 and 14, a mounting substrate 18 is provided with an opening 19 having a square shape. The image sensor according to this embodiment is electrically connected to the mounting substrate 18 with the bumps 29 so that the light receiving elements 1a are formed within the width of the opening 19. In this mounting, optical information is input from the opening 19 of the mounting substrate 18 to the light receiving elements 1a via the transparent cover 21 and the micro-lenses 4.

While in this embodiment, micro-lenses are arranged on the light receiving side of the light receiving elements, similar advantages can be obtained with a structure without micro-lenses.

While in the above embodiment, the image sensor is provided as an example for explanation, it is apparent that the present disclosure is applicable to all other optical devices. For example, the present disclosure is applicable to a light receiving section for a photo IC or a laser diode.

The optical device according to the above embodiments may be integrated into various types of electronic devices. In this case, reduction in image quality can be alleviated in the electronic devices, and testing efficiency is extremely improved, since the first electrodes 6 and 26 are provided on the side of the light incidence. Furthermore, miniaturization of electronic devices can be facilitated.

Note that the first and second embodiments may be implemented in combination with each other.

The optical device of the present disclosure achieves an improvement in testing efficiency, and facilitates miniaturization of an electronic device mounting the optical device, while alleviating degradation in image quality. Therefore, the optical device is expected to be utilized in various electronic devices such as cameras, and is advantageous in improvement in properties of the electronic devices and reduction in the costs and the sizes.

What is claimed is:

1. An optical device comprising:
a semiconductor substrate including
an interconnect layer,
a light receiving section provided with a plurality of light receiving elements on the interconnect layer, and
a peripheral circuit section provided in a same layer as the light receiving section, and surrounding the light receiving section;
light entry elements provided in a region corresponding to the light receiving section on an outer surface of one surface of the semiconductor substrate located above the light receiving section and the peripheral circuit section;
a light shielding film formed of a metal layer, and covering at least one part of a region corresponding to the peripheral circuit section; and
a first electrode formed in the region corresponding to the peripheral circuit section, and in an opening of the light shielding film to be electrically isolated from the light shielding film.

2. The optical device of claim 1, wherein
the first electrode is formed of the metal layer forming the light shielding film.

3. The optical device of claim 1, wherein
the light shielding film has a larger thickness than the light entry elements, and
an end surface of the light shielding film facing the light entry elements has a rough surface.

4. The optical device of claim 1, further comprising
a second electrode provided on an outer surface of the other surface of the semiconductor substrate located under the interconnect layer, wherein
the first electrode and the second electrode are electrically connected together by a conductive body, which is provided to penetrate the semiconductor substrate.

5. The optical device of claim 4, wherein
a bump is formed on a surface of the first electrode.

6. The optical device of claim 1, wherein
in the semiconductor substrate, a lower surface of an insulating film formed on an outer surface of the one surface is flush with an upper surface of the light receiving section or the peripheral circuit section.

7. The optical device of claim 1, wherein
a transparent cover is provided over the one surface of the semiconductor substrate to cover the light entry elements.

8. The optical device of claim 7, further comprising:
a second electrode provided on an outer surface of a surface of the transparent cover, which is on an opposite side to the semiconductor substrate; and
a third electrode provided on an outer surface of the other surface of the semiconductor substrate, wherein
the second electrode and the third electrode are electrically connected together by a conductive body, which is provided to penetrate the semiconductor substrate and the transparent cover.

9. The optical device of claim 8, wherein
a bump is formed on a surface of the second electrode.

10. The optical device of claim 7, wherein
a reinforcement board is provided on the other surface of the semiconductor substrate.

11. The optical device of claim 10, wherein
the transparent cover has a larger thickness than the reinforcement board.

12. The optical device of claim 1, wherein
the light receiving section is an imaging section.

13. An electronic device comprising the optical device of claim 1.
